(19) United States
(12) Patent Application Publication
(10) Pub. No.: US 2008/0026541 A1
(43) Pub. Date: Jan. 31, 2008

(54) AIR-GAP INTERCONNECT STRUCTURES WITH SELECTIVE CAP

(75) Inventors: Daniel C. EDELSTEIN, WHITE PLAINS, NY (US); Satyanarayana V. NITTA, POUGHQUAG, NY (US); Shom PONOTH, FISHKILL, NY (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, Armonk, NY (US)

(21) Appl. No.: 11/460,019

(22) Filed: Jul. 26, 2006

(51) Int. Cl. H01L 21/76

(52) U.S. Cl. 438/421

(57) ABSTRACT

A method of forming a semiconductor structure and the semiconductor structure. The method of manufacturing a structure includes applying a selective cap deposition to at least partially fill perforations, openings, or nano-holes formed above exposed portions of an interconnect during air-gap formation. The structure includes an insulator layer having the interconnect. Air-gaps are formed in the insulator layer. A selective cap deposition at least partially fills or plugs at least one perforations, openings, and nano-holes arranged above exposed portions of the interconnect during formation of the air-gaps.

### FIELD OF THE INVENTION

The invention generally relates to a semiconductor device and method of manufacture and, more particularly, to a semiconductor device and method of manufacturing sub lithographic features within a dielectric material to reduce the effective dielectric constant of such material.

### BACKGROUND OF THE INVENTION

To fabricate microelectronic semiconductor devices such as an integrated circuit (IC), many different layers of metal and insulation are selectively deposited on a silicon wafer. The insulation layers may be, for example, silicon dioxide, silicon oxynitride, fluorinated silicate glass (FSG) and the like. These insulation layers are deposited between the metal layers, i.e., interlevel dielectric (ILD) layers, and may act as electrical insulation therebetween or serve other known functions. These layers are typically deposited by any well known method such as, for example, plasma enhanced chemical vapor deposition (PECVD), chemical vapor deposition (CVD) or other processes.

The metal layers are interconnected by metallization through vias etched in the intervening insulation layers. Additionally, interconnects are provided separately within the dielectric (insulation) layers. To accomplish this, the stacked layers of metal and insulation undergo photolithographic processing to provide a pattern consistent with a predetermined IC design. By way of example, the top layer of the structure may be covered with a photo resist layer of photo-reactive polymeric material for patterning via a mask. A photolithographic process using either visible or ultraviolet light is then directed through the mask onto the photo resist layer to expose it in the mask pattern. An antireflective coating (ARC) layer may be provided at the top portion of the wafer substrate to minimize reflection of light back to the photo resist layer for more uniform processing. The etching may be performed by anisotropic or isotropic etching as well as wet or dry etching, depending on the physical and chemical characteristics of the materials. Regardless of the fabrication process, to maximize the integration of the device components in very large scale integration (VLSI), it is necessary to increase the density of the components.

Although silicon dioxide material has been used as an insulating material due to its thermal stability and mechanical strength, in recent years it has been found that better device performance may be achieved by using a lower dielectric constant material. By using a lower dielectric constant insulator material, a reduction in the capacitance of the structure can be achieved which, in turn, increases the device speed. However, use of organic low-k dielectric materials such as, for example, SiLK (manufactured by Dow Chemical Co., Midland, Mich.) tend to have lower mechanical strength than conventional dielectric materials such as, for example, silicon oxide. In some applications, it has been found that the following materials, in combination with other materials within a device, have a certain effective dielectric constant, such as, for example: (i) undoped silicon glass (USG) has a K of 4.1 and a K_{eff} of approximately 4.3; (ii) USG and fluorosilicate glass (FSG) (K of 3.6) has bilayer K_{eff} of approximately 3.8; (iii) organo silicate glass (OSG) has a K of 2.9 and has a K_{eff} of approximately 3.0; and (iv) porous-OSG has a K of 2.2 and a bilayer of porous-OSG and OSG has a K_{eff} of approximately 2.4.

By building a device having a low-k dielectric or a hybrid low-k dielectric stack, the large intra-level line-to-line component of wiring capacitive coupling is reduced, thus maximizing the positive benefit of the low-k material while improving the overall robustness and reliability of the finished structure. The hybrid oxide/low-k dielectric stack structure is much more robust than an “all low-k” dielectric stack, which is known to be relatively more susceptible to via resistance degradation or via delamination due to thermal cycle stresses driven by the high CTE (coefficient of thermal expansion) of organic and semiorganic low-k dielectrics. However, the overall strength of the dielectric is considerably reduced at the lower dielectric constants.

Nonetheless, even with the lower dielectric constant materials including, for example, a hybrid oxide/low-k dielectric stack structure, there is still the possibility to improve even further the electrical properties of the device by lowering the effective K (K_{eff}) of a multilevel structure or a K of the dielectric material by forming voided channels within the dielectric material between the interconnects and vias. The channels are vacuum filled and have a dielectric constant of about 1. By using such channels, a higher dielectric constant dielectric material, itself, may be used to increase the overall strength of the structure without reducing the electric properties.

In known systems, sub-resolution lithography processes have been used to create such channels. This typically consists of new manufacturing processes and tool sets which add to the overall cost of the fabrication of the semiconductor device. Also, in sub-resolution lithography processes, it is necessary to etch wide troughs in empty spaces which, in turn, cannot be pinched off by ILD PECVD deposition. Additionally, although the channels create low line-line capacitance, there remains a high level-level capacitance for wide lines. This, of course, affects the overall electrical properties of the device. Also, air gaps can occur near the vias from a higher level which creates the risk of plating bath or metal fill at these areas. Lastly, in known processes, there is also the requirement of providing an isotropic etch which may etch underneath the interconnect thus leaving it unsupported or floating and, thus degrading the entire structural and electrical performance of the device.

The present invention is directed to solving these and other problems.

### SUMMARY OF INVENTION

In a first aspect of the invention, a method of manufacturing a structure having air-gaps is provided. The method comprises applying a selective cap deposition to at least partially fill or plug at least one of: perforations formed in a cap layer arranged above exposed portions of an interconnect, openings formed in a cap layer arranged above exposed portions of an interconnect, nano-holes formed in a cap layer arranged above exposed portions of an interconnect; and voids formed in the interconnect.

In a second aspect of the invention, a method of manufacturing a structure comprising forming air-gaps in an insulator layer having at least one interconnect and applying, after the forming, a selective cap deposition to at least partially fill or plug at least one of: perforations formed in a cap layer arranged above exposed portions of an interconnect, openings formed in a cap layer arranged above exposed portions of an interconnect, nano-holes formed in a cap layer arranged above exposed portions of an interconnect, and voids formed in the interconnect.

In a third aspect of the invention, a method of manufacturing a structure having an insulator layer and at least one interconnect is provided. The method comprises etching nano-columns in the insulator layer, forming air-gaps in the insulator layer using an extraction process, and applying a selective cap deposition to at least partially fill or plug perforations, openings, or nano-holes arranged above exposed portions of the at least one interconnect by at least one of the etching and the forming.

In a fourth aspect of the invention, a structure is provided that comprises an insulator layer comprising at least one interconnect, air-gaps formed in the insulator layer, and a selective cap deposition at least partially filling or plugging perforations, openings, or nano-holes formed in a cap layer arranged above exposed portions of the at least one interconnect during formation of the air-gaps.

### BRIEF DESCRIPTION OF DRAWINGS

FIG. 1 is representative of a beginning structure used with the invention;

FIG. 2 is representative of a processing step in accordance with the invention;

FIG. 3 is representative of a processing step in accordance with the invention;

FIG. 4 is representative of a processing step in accordance with the invention;

FIG. 5 is representative of a processing step in accordance with the invention;

FIG. 6 is representative of processing steps in accordance with the invention (and the formed structure);

FIG. 7 is a top view of the formed structure in accordance with the invention;

FIG. 8 is a side cut away view of a multilayered structure formed in accordance with the invention;

FIG. 9 is representative of a processing step in accordance with the invention;

FIG. 10 is representative of a processing step in accordance with the invention;

FIG. 11 is representative of a processing step in accordance with the invention;

FIG. 12 is representative of a processing step in accordance with the invention;

FIG. 13 is representative of a processing step in accordance with the invention;

FIG. 14 is representative of a processing step in accordance with the invention (and the formed structure);

FIG. 15 is representative of a starting structure (in a simplified form) in accordance with another aspect of the invention;

FIG. 16 is representative of an etching process wherein the structure of FIG. 15 is etched to form nano-columns;

FIG. 17 is representative of an extraction process wherein the air-gaps are formed;

FIG. 18 is representative of a selective cap deposition according to the invention;

FIG. 19 is representative of one optional downstream step wherein, after the selective cap deposition, the next level of ILD is deposited; and

FIG. 20 is representative of another optional downstream step wherein, after the selective cap deposition, a second selective cap deposition.

### DETAILED DESCRIPTION

This invention is directed to a semiconductor device and methods of manufacture for providing channels (or pores) in a dielectric (insulator) material to improve overall device performance. The methods of the invention do not require new manufacturing processes or tool sets nor do they introduce new materials into the final build and further avoid many of the shortcomings of sub-resolution photolithographic processes. Additionally, the methods of the invention are easily adaptable for use with any dielectric material, whether a hybrid structure or a material having a high dielectric constant. The invention, in one aspect, prevents floating interconnects and also, while decreasing the effective dielectric constant, K_{eff}, may maintain the low level-level vertical capacitance of the interconnects. The overall device strength may also be maintained using the methods of the invention. Such a structure and process is disclosed in US Patent Application Publication No. 2005/0167838 which published on Aug. 4, 2005, the disclosure of which is hereby expressly incorporated by reference in its entirety.

The invention also aims to provide a good Cu/cap interface, which is necessary to prevent electromigration related early fails. In the di-block integration scheme for the formation of air-gap interconnect structures, there exists the possibility of damaging the copper during the etching process (which is utilized to damage the ILD) and the subsequent wet extraction steps. This may detrimentally affect interconnect reliability if the second cap deposition does not completely coat the exposed copper surface or if it results in a poor Cu/cap interface. The invention aims to address the problem by utilizing of a selective cap deposition such as, e.g., CoWP, CoWB or CuSiN, after the extraction process that is used to create the air-gaps. Both these processes have the potential of restoring a good Cu/cap interface. Due to the selective nature of the deposition, the air-gap in the ILD regions can be left relatively intact.

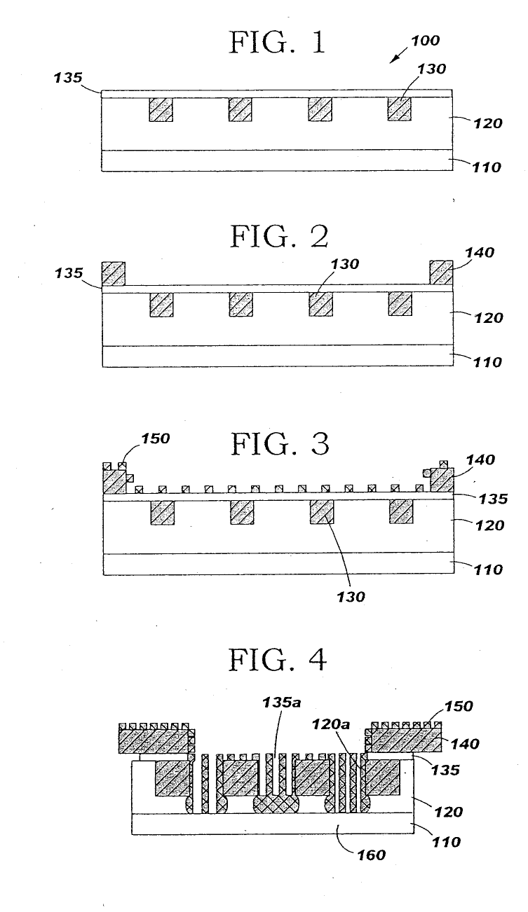

FIG. 1 shows a conventionally manufactured structure used in a semiconductor device. This structure, generally represented as reference numeral 100, is a single level structure, i.e., single wiring layer, shown for illustrative purposes; however, it should be readily understood by those of skill in the art that the structure shown and described herein can be a multilevel structure of several different layers. The methods of manufacturing described herein are equally applicable to such a multilevel structure.

The structure 100 of FIG. 1 includes a substrate 110 of any conventional material such as, for example silicon. The substrate may be an integrated circuit built up to a wiring level. An insulation layer 120 is deposited on the substrate 110 using any known method such as, for example, plasma enhanced chemical vapor deposition (PECVD), chemical vapor deposition (CVD) or other processes. The insulation layer 120 may be, for example: (i) undoped silicon glass (USG), (ii) USG and fluorosilicate glass (FSG), (iii) organo silicate glass (OSG), (iv) porous-OSG and OSG, (v) any combination of these materials or any other known dielectric material. The insulation layer 120, in one implementation, is preferably either OSG or a layered structure of OSG and porous-OSG. One or more interconnects 130 are formed in the insulation layer 120. A diffusion barrier layer 135 which may be SiC, SiN or other known material, as discussed herein, is deposited on the insulation layer 120 to protect the interconnects 130. The diffusion barrier layer 135 may additional act as an etch mask in subsequent processes. The diffusion barrier layer 135 may be at a thickness in the range of 250 Å to 500 Å, or other thicknesses depending on the application.

FIG. 2 is representative of a first step of the method of the invention. In this step, a blockout patterned resist 140 (supra lithographic mask) is deposited or formed on the diffusion barrier layer 135. The blockout patterned resist 140 is, in one implementation 2000 Å to 1 micron in thickness and is deposited in any conventional manner. The blockout patterned resist 140 may be any conventional photoresist material. The blockout patterned resist 140 includes holes or features that are larger than the minimal resolution features; that is, in one implementation, the features of the blockout patterned resist 140 are larger than the spacings between the interconnects 130.

FIG. 3 is representative of a second step of the invention. In FIG. 3, a block copolymer nanotemplate 150 is formed over the blockout patterned resist 140 and portions of the diffusion barrier layer 135. The block copolymer nanotemplate 150 is a thin layer having features smaller than the minimal resolution features. In other words, the features of the block copolymer nanotemplate 150 are smaller, in one implementation, than the spacings between the interconnects 130. The block copolymer nanotemplate 150 may be a material which self assembles itself into substantially uniformly shaped and spaced holes or features. For example, the block copolymer nanotemplate 150 may be a self assembled monolayer templated porous or permeable film. The block copolymer nanotemplate 150 may be e-beam, “uv” or thermally cured. It should be further recognized that in implementations, the blockout pattern resist 140 may instead be formed over the block copolymer nanotemplate 150.

In one implementation, the holes of the block copolymer nanotemplate 150 are about 20 nm in diameter with a spacing of about 20 nm therebetween. In other implementations, the spacings and diameter of the features may range, for example, from below 5 nm to 100 nm. The thickness of the block copolymer nanotemplate 150, in one implementation, is approximately 20 nm and is made from an organic polymer matrix having a mesh of holes. It should be understood, though, that the thickness of the block copolymer nanotemplate 150 (and blockout resist) may vary depending on the thickness of the insulation layer, the required feature resolution and other factors, all of which can be ascertained by one of ordinary skill in the art in view of the description herein.

FIG. 4 shows an etching step of the invention. Now that the block copolymer nanotemplate 150 and the diblock patterned resist 140 are formed on the structure, an etch, in one implementation, using RIE is used to form channels 160 or nano columns between the interconnects 130. In this step, as the insulator is etched between the holes of the block copolymer nanotemplate 150, the insulation layer 120 may be deliberately eroded to form one or more nano column between adjacent interconnects. In some implementations, the insulation layer may be eroded to the substrate or lower layer level. In this step, since no etch process is infinitely selective, the block copolymer nanotemplate 150 may also begin to erode; however, the features of the block copolymer nanotemplate 150 are transferred to the diffusion barrier layer 135, which will then act as the mask having the transferred features. An undercut below the interconnects may also be formed.

As seen in FIG. 4, small holes 135a, i.e., approximately equal to the channels 160, remain at the surface of the insulation material 120, basically corresponding to the size of the features of the block copolymer nanotemplate 150. The holes 135a may be on the order of 20 Å to 200 Å in diameter, for example. Additionally, during etching, insulation material 120a may be etched from the sidewalls of the interconnects 130, but redeposited in further depositing steps. In one implementation, the sidewall material 120a may be in the thickness range between 5 Å and 200 Å, with a thicker portion of the sidewall proximate to the block copolymer nanotemplate 150 or diffusion barrier layer 135. It should be understood by those of skill in the art that the masks 140 and 150, as well as the etching process may be tuned to control the pattern to thus, for example, preclude gaps near via lands and the like. Also, by tuning the etching process(s), the channels 160 may extend partially or completely through the insulation layer 120, or the insulation layer near the sidewalls of the interconnects may be completely or substantially completely eroded. In this latter situation, deposition of insulation material near the sidewalls may be provided during a subsequent step of forming a higher interconnect layer.

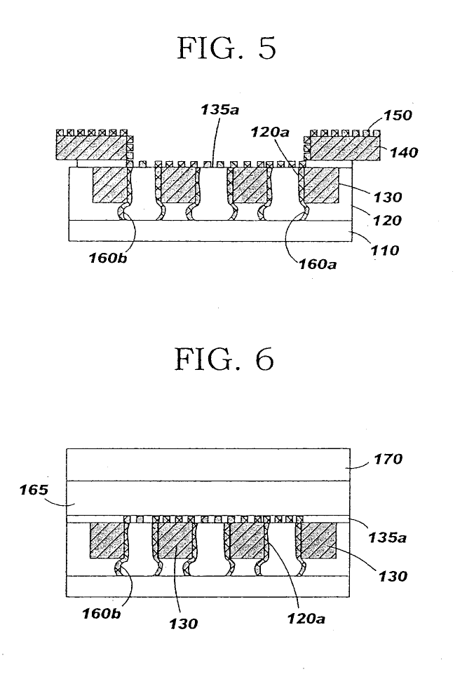

The RIE, is an anisotropic etch, etching primarily straight down, in order to etch away the insulation to form the channels 160. The RIE etch may be followed by a wet clean process to remove any polymer residue resulting from the etching process. This cleaning chemistry may contain an etchant to continue isotropic etching of the insulation layer to form an undercut below the interconnects (FIG. 5). The etching of insulation layers comprising USG or FSG is relatively slow using dilute hydrofluoric acid (DHF). For example, the etch rate may be 10 Å to 20 Å per minute at a H₂O:HF ratio of 200:1.

On the other hand, OSG has a very low chemical etch rate in DHF, which is almost immeasurable. In OSG implementations, RIE with plasma O₂ is used to provide more complete etch capabilities by oxidizing or “damaging” the first skin layer of the exposed OSG. Then, this damaged layer will etch very readily in this DHF. However, when using O₂, there is the possibility of damaging the OSG insulation layer or diffusion layer. This damage can be corrected by providing another etch to the damaged portions.

FIG. 5 represents an isotropic etching step to enlarge the nano columns into a single larger column 160a than the original holes of the block copolymer nanotemplate 150, in addition to providing an undercut to the formed channels. In this step, the RIE is changed by adding, for example, O₂. In this step, the isotropic etch forms the undercuts 160b, but should not etch away the entire area under the interconnects 130. Again, the etching can be tuned to provide for more extreme undercuts, depending on the desirability of the performance of the overall device; however, the undercut is preferably not performed under the entire area below the interconnects 130. In one implementation, the undercuts will reduce vertical capacitance of wide lines.

FIG. 6 represents other processing steps of the invention. For example, after the undercuts are formed, the block copolymer nanotemplate 150 and the blockout level patterned resist 140 are etched or stripped, leaving behind the small holes 135a. These masks may have already eroded, entirely or partially, during the etching processes, thus leaving the diffusion barrier layer 135 as the mask. A wet etch process can also be performed with solvent, DHF, or other acids to etch away any dielectric material which was previously damaged. In one implementation, the DHF is in a concentration from about 1000:1 to 10:1H₂O:HF. In an aspect of the invention, by widening the channels 160, backfill material having a different dielectric constant and other properties, e.g., higher ductability, higher fracture toughness, etc., may be provided within the channels.

Still referring to FIG. 6, a second insulation layer 170 is then deposited on the thus formed structure using any conventional depositing method such as, for example, PEVCD. The second insulation layer 170 may include a cap 165 which will, after little deposition, cover the interconnects 130 (e.g., copper wires) and the diffusion barrier layer 135, as well as forming pinch off areas 135, in addition to sealing the channels. The cap layer 165 will, in embodiments, minimize topography. The pinch off portions 135a may range between, for example, 20 Å to 200 Å, which are sub lithographic features. The pinch offs may act to minimize any level to level capacitance issues between adjacent layers.

During the initial deposition of insulation material, the small size of the holes 135a substantially eliminates significant thickness of material from being deposited within the columns 160. The material for the second layer of insulation layer 170 may be, for example, (i) undoped silicon glass (USG), (ii) USG and fluorosilicate glass (FSG), (iii) organo silicate glass (OSG), (iv) porous-OSG and OSG, (v) any combination of these materials or any other known dielectric material. The insulation layer 170, in one implementation, is preferably either OSG or a layered structure of OSG and porous-OSG, with the OSG acting as the cap 165 for sealing the columns.

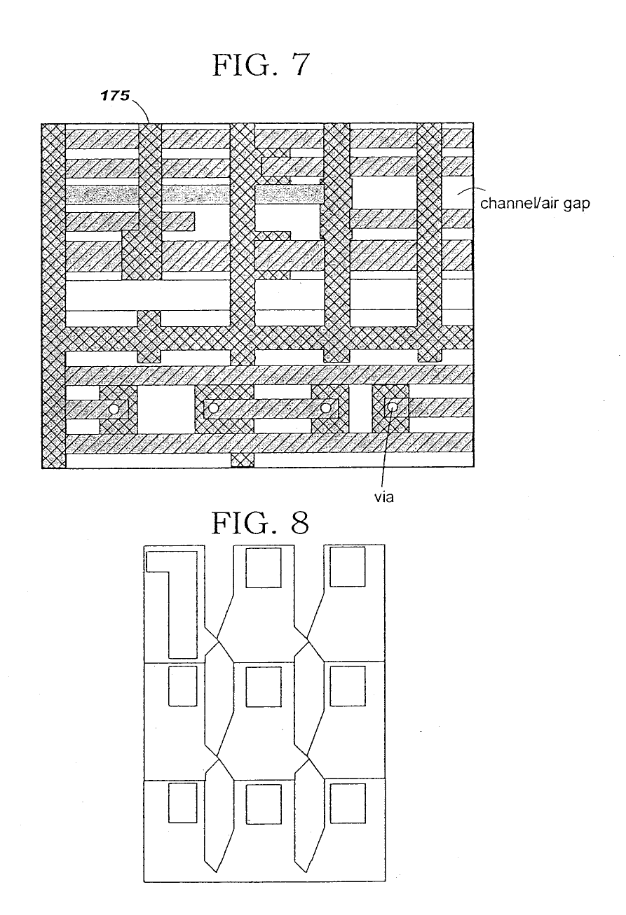

FIG. 7 shows a top view of the formed structure according to an aspect of the invention. In this view, blockout resist patterns 175 may be formed using the blockout patterned resist. The blockout resist patterns 175 may be used to provide additional mechanical reinforcement to the formed structure at locations other than the formed channels. By way of one example, the blockout resist patterns 175 may be formed over the scribe lanes or over the vias to provide additional strength and prevent pores in the vicinity of the sawing operation. It should be recognized that channels in the scribe lane may result in catastrophic failure due to shattering of the fragile material. The blockout resist patterns 175 may also enable dielectric reinforcement with concurrent extreme cutout, and also to avoid or prevent gaps from forming near the via regions.

It should be understood that the steps and structure of the invention, as described above, may be repeated for higher level insulation layers. Thus, as shown in FIG. 7, several insulation layers having vias, interconnects and channels may be formed using the methods of the invention. It should also be understood that by providing the channels, the effective dielectric constant of the insulation materials can be reduced without significantly affecting the integrity, robustness and strength of the entire device. In fact, the methods of the invention can achieve a K_{eff} of less than 2.0 with materials having a K_{eff} of 2.7 or greater. Additionally, by using the method of the invention, porous materials can be avoided for use in the insulation layer thus increasing the mechanical strength and thermal capabilities of the device, i.e., allowing the heat to transfer downward to the substrate. This structure may also be formed by other methods described herein.

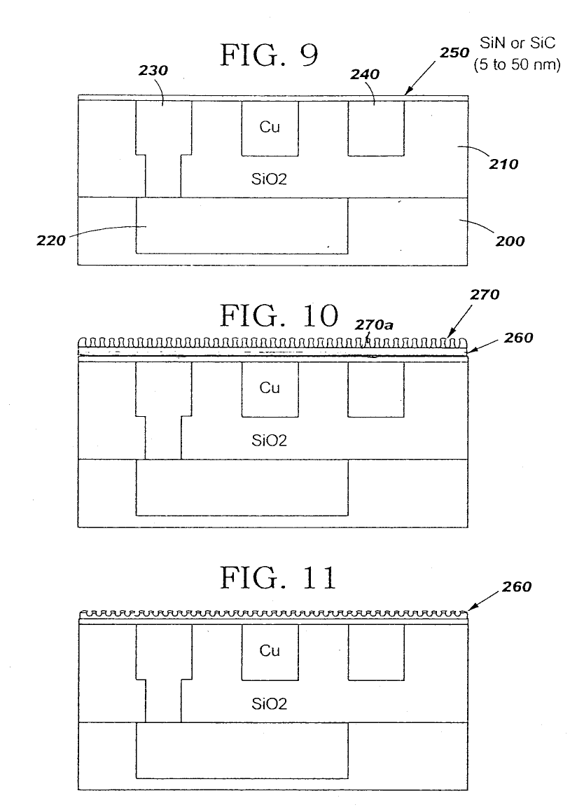

FIGS. 9 though 14 show another embodiment of the invention. FIG. 9 is representative of a structure having two insulation layers 200 and 210, of any type discussed above. For example, the insulation layer 210 may be SiO₂, FSG, SiCOH, SiLK or other materials. The insulation layer 200 includes an interconnect 220 and the insulation layer 210 includes a via 230 and several interconnects 240. A dielectric cap, such as SiN, SiC, SiCOH, etc. (diffusion layer) 250 is deposited over the insulation layer 210 and interconnects. The cap 250 ranges, in one implementation, from 5 nm to 50 nm in thickness. An SiO₂ cap may be provided if the interconnect, e.g., copper wire, is capped. Multiple layers of these materials or any combination may also be used with the invention. It should be understood that this same or similar feature is applicable to other embodiments discussed herein.

Referring now to FIGS. 10 through 14, a blanket deposition layer 260 of SiO₂ followed by a deposition layer 270 of Au, Ag, In, Sn or Ga in the range from 5 nm to 50 nm is provided on the cap 250. It should be understood that a blockout patterned resist may be deposited between the deposition layers 260 and 270, or alternatively above the deposition layer 270. As in the previous embodiment, the blockout patterned resist should be a supra lithographic mask for preventing the formation of gaps over larger areas of the device. Metals which can easily dissolve in acids, acid salts and alkaline solutions such as Sn or In may be used in the invention in order to provide for easier removal at a later stage; however, other metals are also contemplated for use with this aspect of the invention. The layer 270 is treated, e.g., annealed, to cause agglomeration (i.e., beading) in order to form sub lithographic features in the range of 1 nm to 50 nm. In this manner, nano islands 270a are formed from the layer 270, which act as a mask for further processing steps. The layer 270 is in the range of 1 nm to 50 nm in thickness and, in one implementation, in the range of 5 nm and 20 nm in thickness.

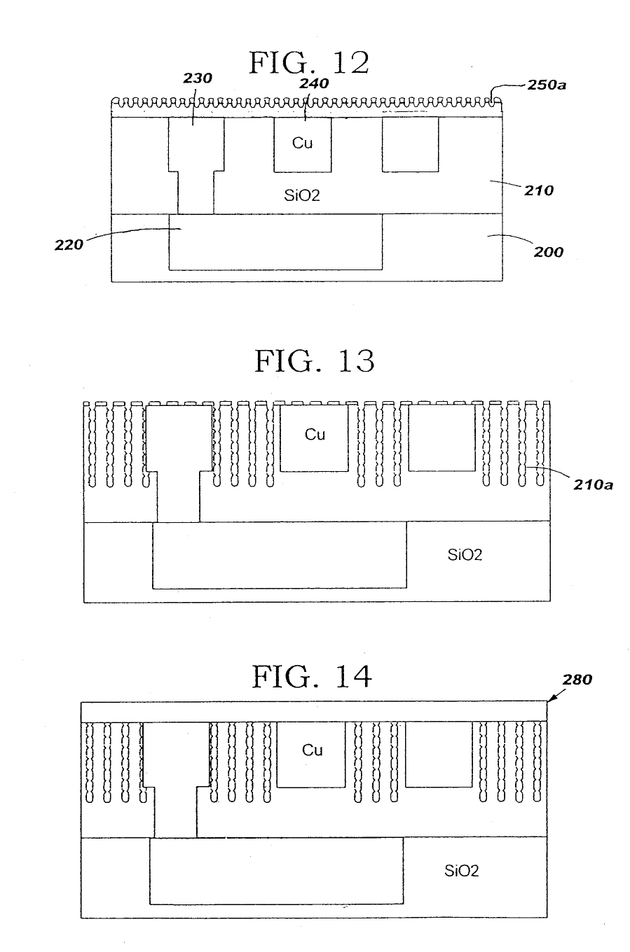

In FIG. 11, pores are etched in layer 260. This etching may be performed by RIE, in a conventional manner. The metal islands 270a are stripped with a wet or dry etch, and etching continues with RIE into the layer 250. An underlying hardmask may be used to protect the underlying structures during removal of the metal islands 270a such as the cap 250. This RIE etching forms the channels or pores 250a (FIG. 12). Etching continues into the SiO₂ layer 210 forming pores or nano channels 210a substantially the same size as the sub lithographic features of layer 270 in the range of 1 nm to 50 nm. The RIE etching is, in one implementation, an anisotropic etch.

A dielectric cap layer 280, such as SiO₂, which can be deposited using PECVD or any known method, is deposited on the insulation layer 210 to seal the channels 250a (FIG. 14). The dielectric cap 280 may have a thickness range of 5 nm to 50 nm, in one aspect of the invention. (Of course, other thicknesses, as with all other materials used herein, are also contemplated by the invention.) The dielectric cap 280 may equally be other materials such as SiC, SiCOH or SiN, for example. In one embodiment, the nano channels may be filled with a tough dielectric prior to the sealing with the capping dielectric layer. Pinch off sections may be formed in the capping dielectric layer 280.

In aspects of this embodiment, a random hole pattern in resist may be formed using e-beam, x-ray or EUV lithography. In this case, the resists mask the regions where the dielectric is left behind and the vertical pores or columns are etched into the dielectric. A hardmask such as Nitride may be used underneath the resist if the dielectric is an organic material.

As a further alternative, a random hole pattern in a 2-phase polymer mask with porogen may be utilized to form the pores. To fabricate the mask, the polymer is applied and the porogen is then removed with a high temperature cure or with solvent, as is well known in the art. This will form the sub lithographic holes for further processing. There would be no need for optical lithographic exposure or photomask in this or other processes. The vertical pores or nano columns would then be etched in the manner discussed above.

Alternatively, a spin on film with fine metal particles such as a metal sol may be used to form the required holes, as may be represented by layer 270. In this process, a single layer of fine metal particles from a sol are deposited. This may be performed by pre-treating the layer 260 with a surfactant that forms a monolayer in the surface and attracts the sol particles to the surface to form a layer of the sol particles. That is, the layer would be burned away to leave metal particles on the surface which then could be used for the mask. A phase separable spin on solution such as block copolymer can also be used as the mask. In addition, in this embodiment, selective masking can be used to selectively add toughening to critical areas of the chip, such as discussed with reference to FIG. 7.

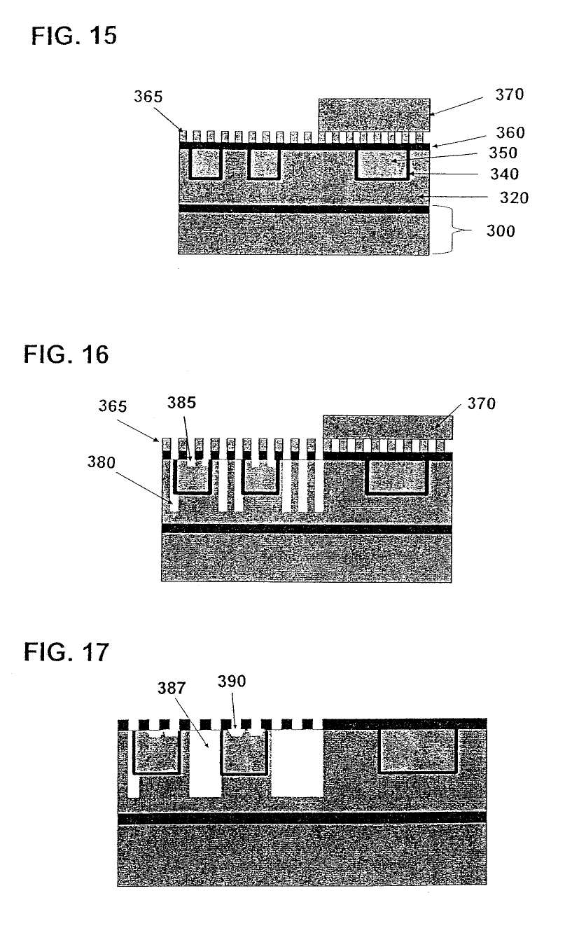

FIG. 15 shows a schematic cross section view of a simplified starting structure that can be made by the process described above. Layer 300 represents an underlying build such as substrate. The layer 320 is built on the substrate 300 with an appropriate dual damascene scheme. Layer 320 has the form of a dielectric material and can be a porous or dense material comprised of Si, C, O and H. The metallization is represented by reference number 340 and can be a liner material similar. Interconnects 350 can be copper or any appropriate conductive metal and can be similar to interconnects 130 discussed above. A cap layer 360 can be utilized on the structure and can be similar to layer 135 discussed above. A patterning layer 365 is arranged on top of layer 360. This layer 365 can be similar to layer 150 discussed above and can be a high density material having vias/holes 365. The size of the holes 365 can be the same as the holes of layer 150. The layer 365 can be created by self assembly techniques, such a diblock copolymer designed to have perpendicularly oriented cylinders. Regions where air-gaps are not desired can be blocked out using a ‘block-out’ resist layer 370. Layer 370 can be similar to layer 140 discussed above.

FIG. 16 illustrates an etch step which can be similar to the etching step shown in FIG. 4. The etching forms nano-columns 380 in the ILD or layer 320. These nano-columns 380 can be similar to the channels 160 discussed above. The etching is followed with an intentionally damaging strip chemistry to remove residual photoresist and residual transfer layer, and to damage the ILD for easy extraction in the next step. As can be seen in FIG. 16, the process can possibly result in exposed surfaces of the copper interconnect being damaged or sputtered. This damage can be in the form of depressions and/or indentations and/or voids 385, and can occur either during the nano-columnar etch or during the strip step(s).

The nano-columnar etch step (FIG. 16) is followed by a process in which the intentionally damaged ILD is extracted out to leave behind air-gaps 387. This step is illustrated in FIG. 17. Dilute HF dip represents one non-limiting way in which an “extraction” process can be used to remove layer 365 and 370. However, as illustrated in FIG. 17, the extraction process (and the wet chemistry used therein) can possibly attack the copper surface exposed during the nano-columnar RIE etch, and further erode the copper to form even larger voids 390 in the copper interconnects.

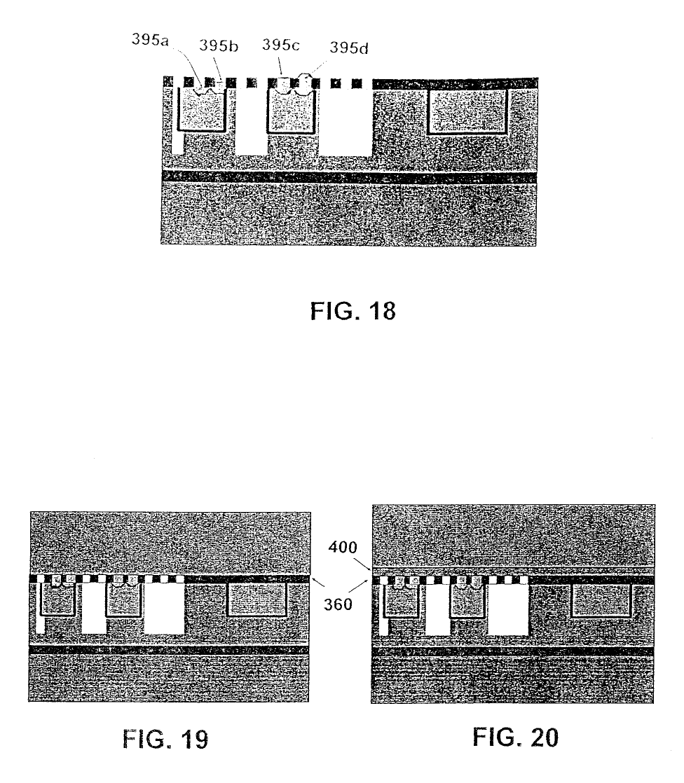

FIG. 18 illustrates one non-limiting way of addressing the problem of damage to the copper interconnects. Instead of applying a pinch-off cap deposition layer following the step shown in FIG. 17 (as described in previous embodiments), the invention aims to first correct the damage to the copper interconnects. Depending on the conformality of the second cap deposition and the profile of the voids 390 in the copper, the voids 390 may or may not be filled. According to one solution, a selective cap is deposition such that the exposed areas of the copper are selectively covered with a cap material. The use of a selective deposition cap is a well studied process and is usually designed to deposit a cap only on copper.

FIG. 18 illustrates the structure subsequent to such a selective metal cap deposition. The selective nature of the process means that there is no deposition in air-gap regions. That is, only areas of the copper or interconnect need to be exposed to the cap. Furthermore, the cap deposition need not be evenly applied to all select areas. For example, different fill amounts can be utilized in different areas as represented by 395a, 395b, 395c and 395d. Alternatively, all of the select areas can be filled to the point of e.g., 395a, or 395b, or 395c, or 395d. In reality, the process would result in approximately the same fill amount in each of the areas across the wafer.

By way of non-limiting example, thin layer 395a can have a thickness in the range of between approximately 10 Å and 100 Å. Thicker layer 395b can have a thickness in the range of between approximately 100 Å and 200 Å. An even thicker layer 395c can have a thickness in the range of between approximately 200 Å and 500 Å. Finally, thickest layer 395d, which forms a complete plug, can have a thickness in the range of between approximately 500 Å and 1000 Å. Non-limiting examples of the selective cap material can include CoWP, CoWB and CuSiN. It is also noted that this process is applicable to any air gap structure and should not be limited to a di-block integration scheme.

FIGS. 19 and 20 illustrate optional steps which can be employed after the selective metal cap deposition. FIG. 19 shows one downstream processing step in which the selective metal cap step shown in FIG. 18 is immediately followed by the next level ILD deposition. FIG. 20 shows one downstream processing step in which the selective metal cap step is followed by a second cap deposition 400. The layer 400 can have a thickness in the range of between approximately 250 Å and 500 Å.

Although FIGS. 16-20 show the process forming voids 385 and 390 formed in the interconnect 350, the invention also contemplates a process wherein voids or indentations are not substantially formed in the interconnect 350 and instead the openings, perforations, or nano-holes which are formed in the cap layer 360 above exposed portions of the interconnect 350 are at least partially filled or plugged by e.g., portions 395b, or 395c, or 395d.

Non-limiting examples of the selective cap material 400 can include CoWP, CoWB and CuSiN. The cap material 400 may or may not be the same material as the cap material 360. The choice between the steps shown in FIG. 19 or 20 would depend on the properties of the selective cap. If the selective cap material can replace the cap 360 material in terms of it having all the desired properties, then the scheme resulting in the structure of FIG. 19 may be used. In the case where it does not meet the oxygen and copper diffusion barrier properties that are required, the structure shown in FIG. 20 may be used in which a second cap deposition 400 is performed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the invention has been described in terms of embodiments, those skilled in the art will recognize that the invention can be practiced with modifications and in the spirit and scope of the appended claims.

What is claimed:

1. A method of manufacturing a structure having air-gaps, comprising:
applying a selective cap deposition, during air-gap formation, to at least partially fill or plug at least one of:
perforations formed in a cap layer arranged above exposed portions of an interconnect,
openings formed in a cap layer arranged above exposed portions of an interconnect,
nano-holes formed in a cap layer arranged above exposed portions of an interconnect, and
voids formed in the interconnect.

2. The method of claim 1, further comprising, before the applying, at least one of:
forming the perforations in the cap layer;
forming the openings in the cap layer;
forming the nano-holes in the cap layer; and
forming the voids with an extraction process.

3. The method of claim 2, wherein the extraction process comprises one of an HF dip process and a wet chemistry process.

4. The method of claim 1, wherein the interconnect is a copper interconnect.

5. The method of claim 1, further comprising, before the applying, subjecting the structure to etching to form nano-columns in an underlying insulator layer.

6. The method of claim 1, further comprising, before the applying, subjecting the structure to etching to form nano-columns in an insulator layer and thereafter subjecting the structure to an extraction process.

7. The method of claim 6, wherein the voids are formed by subjecting the structure to the extraction process.

8. The method of claim 6, wherein the voids are formed by subjecting the structure to etching to form nano-columns and thereafter the voids are made larger by subjecting the structure to the extraction process.

9. The method of claim 1, wherein the selective cap deposition comprises one of CoWP, CoWB and CuSiN.

10. The method of claim 1, wherein the applying comprises at least one of applying a layer of selective cap deposition to only substantially fill the perforations, the openings, the nano-holes or the voids, applying a layer of selective cap deposition to overfill the voids, applying a layer of selective cap deposition to only fill the perforations, the openings, the nano-holes or the voids with substantially the same amount of material, applying a layer of selective cap deposition to overfill fill the perforations, the openings, the nano-holes or the voids with substantially the same amount of material, and applying different amounts of the selective cap deposition to different perforations, openings, nano-holes or voids.

11. A method of manufacturing a structure, comprising:
forming air-gaps in an insulator layer having at least one interconnect; and
applying, after the forming, a selective cap deposition to at least partially fill or plug at least one of:
perforations formed in a cap layer arranged above exposed portions of an interconnect,
openings formed in a cap layer arranged above exposed portions of an interconnect,
nano-holes formed in a cap layer arranged above exposed portions of an interconnect, and
voids formed in the interconnect.

12. The method of claim 11, wherein the forming comprises an extraction process.

13. The method of claim 12, wherein the extraction process comprises one of an HF dip process and a wet chemistry process.

14. The method of claim 11, wherein the interconnect is a copper interconnect.

15. The method of claim 11, wherein the forming comprises subjecting the structure to etching to form nano-columns in the insulator layer.

16. The method of claim 11, wherein the forming comprises subjecting the structure to etching to form nano-columns in the insulator layer and thereafter subjecting the structure to an extraction process to form the air-gaps.

17. The method of claim 11, wherein the selective cap deposition comprises one of CoWP, CoWB and CuSiN.

18. The method of claim 11, wherein the applying comprises one of applying a layer of selective cap deposition to only substantially fill the perforations, the openings, the nano-holes or the voids, applying a layer of selective cap deposition to overfill the perforations, the openings, the nano-holes or the voids, applying a layer of selective cap deposition to only substantially fill the perforations, the openings, the nano-holes or the voids with substantially the same amount of material, applying a layer of selective cap deposition to overfill the perforations, the openings, the nano-holes or the voids with substantially the same amount of material, and applying different amounts of the selective cap deposition to different perforations, openings, nano-holes or voids.

19. A method of manufacturing a structure having an insulator layer and at least one interconnect, comprising:
etching nano-columns in the insulator layer;
forming air-gaps in the insulator layer using an extraction process; and
applying a selective cap deposition to at least partially fill or plug perforations, openings, or nano-holes arranged above exposed portions of the at least one interconnect by at least one of the etching and the forming.

20. A structure, comprising:
an insulator layer comprising at least one interconnect;
air-gaps formed in the insulator layer; and
a selective cap deposition at least partially filling or plugging perforations, openings, or nano-holes formed in a cap layer arranged above exposed portions of the at least one interconnect during formation of the air-gaps.
